(19) United States
(12) Patent Application Publication
(10) Pub. No.: US 2018/0196354 A1
(43) Pub. Date: Jul. 12, 2018

(54) A LITHOGRAPHIC APPARATUS, A PROJECTION SYSTEM, A LAST LENS ELEMENT, A LIQUID CONTROL MEMBER AND A DEVICE MANUFACTURING METHOD

(71) Applicant: ASML NETHERLANDS B.V., Veldhoven (NL)

(72) Inventors: Cornelius Maria ROPS, Waalre (NL); Willem Jan BOUMAN, Moergestel (NL); Theodorus Wilhelmus POLET, Geldrop (NL)

(73) Assignee: ASML NETHERLANDS B.V., Veldhoven (NL)

(21) Appl. No.: 15/741,763

(22) PCT Filed: Jul. 13, 2016
(86) PCT No.: PCT/EP2016/066691

§ 371 Date: Jan. 3, 2018

(30) Foreign Application Priority Data
Jul. 16, 2015 (EP) 15177080.7

(51) Int. Cl. G03F 7/20; H01L 21/027; G02B 27/00

(52) U.S. Cl. CPC G03F 7/70341; G03F 7/70891; G02B 27/0006; G03F 7/70808; H01L 21/0274; G03F 7/70958

(57) ABSTRACT

A lithographic apparatus includes a projection system configured to project a patterned radiation beam through the projection system onto a target portion of a substrate. A liquid confinement structure confines an immersion liquid in a space between the projection system and the substrate. The projection system includes: an exit surface through which to project the patterned radiation beam; and a further surface facing the liquid confinement structure. The further surface has a first static receding contact angle with respect to the immersion liquid. The exit surface has a second static receding contact angle with respect to the immersion liquid. The first static receding contact angle is: greater than the second static receding contact angle; and less than 65 degrees.

### CROSS-REFERENCE TO RELATED APPLICATIONS

This application claims priority of EP application 15177080.7 which was filed on Jul. 16, 2015 and which is incorporated herein in its entirety by reference.

### FIELD

The present invention relates to a lithographic apparatus, a projection system for use with an immersion lithographic apparatus, a last lens element for a projection system, a liquid control member, and a device manufacturing method.

### DESCRIPTION OF THE RELATED ART

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Conventional lithographic apparatus include ‘steppers’ and ‘scanners’. In a stepper each target portion is irradiated by exposing an entire pattern onto the target portion at once. In a scanner, each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

Immersion techniques have been introduced into lithographic systems to enable improved resolution of smaller features. In an immersion lithographic apparatus, a liquid layer of a liquid having a relatively high refractive index is interposed in a space between a projection system of the apparatus (through which the patterned beam is projected towards the substrate) and the substrate. The liquid covers at last the part of the substrate under the last lens element of the projection system. Thus, at least the portion of the substrate undergoing exposure is immersed in the liquid. The effect of the immersion liquid is to enable imaging of smaller features since the exposure radiation will have a shorter wavelength in the liquid than gas. (The effect of the liquid may also be regarded as increasing the effective numerical aperture (NA) of the system and also increasing the depth of focus.)

In commercial immersion lithography, the liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space as immersion liquid. Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the space between the last lens element and a surface facing the last lens element. The facing surface is a surface of the substrate or a surface of the supporting stage (or substrate table) that is co-planar with the substrate surface. (Please note that reference in the following text to surface of the substrate W also refers in addition or in the alternative to a surface of the substrate table, unless expressly stated otherwise; and vice versa). A fluid handling structure present between the projection system and the substrate table is used to confine the immersion liquid to the immersion space. The space filled by liquid is smaller in plan than the top surface of the substrate and the space remains substantially stationary relative to the projection system while the substrate and substrate table move underneath.

Other immersion systems have been envisaged such as an unconfined immersion system (a so-called ‘all wet’ immersion system) and a bath immersion system. In an unconfined immersion system, the immersion liquid covers more than the surface under the last lens element. The liquid outside the immersion space is present as a thin liquid film. The liquid may cover the whole surface of the substrate or even the substrate and the substrate table co-planar with the substrate. In a bath type system, the wafer is fully immersed in a bath of liquid.

The fluid handling structure is a structure which supplies liquid to the immersion space, removes the liquid from the space and thereby confines liquid to the immersion space. It includes features which are a part of a fluid supply system. The arrangement disclosed in PCT patent application publication no. WO 99/49504 is an early fluid handling structure comprising pipes which either supply or recover liquid from the space and which operate depending on the relative motion of the substrate table beneath the projection system. In more recent designs the fluid handling structure extends along at least a part of a boundary of the space between the last lens element and the substrate table or substrate, so as to in part define the immersion space.

The fluid handing structure may have a selection of different functions. Each function may be derived from a corresponding feature that enables the fluid handling structure to achieve that function. The fluid handling structure may be referred to by a number of different terms, each referring to a function, such as barrier member, seal member, fluid supply system fluid removal system, liquid confinement structure, etc.

As a barrier member, the fluid handling structure is a barrier to the flow of the immersion liquid from the space. As a liquid confinement structure, the structure confines liquid to the space during use. As a seal member, sealing features of the fluid handling structure form a seal to confine liquid to the space. The sealing features may include an additional gas flow from an opening in the surface of the seal member, such as a gas knife.

In an embodiment the fluid handling system may supply immersion liquid and therefore be a liquid supply system.

A lithographic projection apparatus has a projection system (e.g. an optical projection system). During exposure of a substrate, the projection system projects a beam of patterned radiation onto the substrate. In an embodiment, to reach the substrate the path of the beam passes from the projection system through a liquid confined by the liquid confinement structure between the projection system and the substrate. The projection system has a lens element, the last in the path of the beam, which is in contact with the immersion liquid. This lens element which is in contact with the immersion liquid may be referred to as ‘the last lens element’. The last lens element is sometimes referred to as a WELLE lens. The last lens element is at least partly surrounded by the liquid confinement structure. The liquid confinement structure may confine liquid under the last lens element and above the facing surface.

In some immersion lithographic apparatus, there is a gap between the liquid confinement structure and the last lens element. A free meniscus of the immersion liquid may be located in the gap. The meniscus is an interface between liquid and gas. The liquid of the meniscus evaporates into the gas thereby applying a thermal load on the liquid confinement structure and the projection system. The thermal load may cause thermal (e.g., cold) spots on the projection system. Depending on the location of the meniscus, the thermal spots may cause optical aberrations, which may contribute to focus irregularities and may affect performance in terms of the resulting image overlay accuracy (or ‘overlay’).

During exposure, the substrate table is moved relative to the liquid confinement structure (and the projection system). The movement may cause the level of the immersion liquid in the gap to change. The movement may comprise a meandering movement in order to achieve a repetitive back and forth motion in the scanning direction. The resulting movement of the meniscus in between the lens and the liquid confinement structure is oscillatory. The oscillatory movement of the immersion liquid meniscus may be referred to as ‘sloshing’. The sloshing may cause a thin liquid film to be left on a surface of the projection system. The liquid film may evaporate and apply a thermal load to the projection system.

A material that is liquidphobic with respect to the immersion liquid (i.e. which is such that a droplet of the immersion liquid on a surface of the material would have a static contact angle of 90 degrees or more) may be provided on an external surface of the projection system in the region of the gap. During sloshing, the liquidphobic material can help prevent the immersion liquid from moving too far upwards or outwards along the gap, or from remaining in contact with the lens to an undesirable extent after the meniscus has receded.

It has been observed that the effectiveness of the liquidphobic material in reducing heat load to the projection system degrades after a period of time. To maintain performance the liquidphobic material therefore needs to be replaced intermittently and with increasing frequency. Replacement increases downtime and reduces productivity.

It is an object of the invention to provide alternative apparatus and methods for reducing a thermal load applied to the projection system due to evaporation of immersion liquid.

### SUMMARY

According to an aspect, there is provided a lithographic apparatus, comprising: a projection system configured to project a patterned radiation beam through the projection system onto a target portion of a substrate; and a liquid confinement structure configured to confine an immersion liquid in a space between the projection system and the substrate, the projection system comprising: an exit surface through which to project the patterned radiation beam; and a further surface facing the liquid confinement structure, wherein: the further surface has a first static receding contact angle with respect to the immersion liquid; the exit surface has a second static receding contact angle with respect to the immersion liquid; and the first static receding contact angle is: greater than the second static receding contact angle; and less than 65 degrees.

According to an aspect, there is provided a lithographic apparatus, comprising: a projection system configured to project a patterned radiation beam through the projection system onto a target portion of a substrate; and a liquid confinement structure configured to confine an immersion liquid in a space between the projection system and the substrate, the projection system comprising: an exit surface through which to project the patterned radiation beam; and a further surface facing the liquid confinement structure, wherein: the liquid confinement structure is configured so that movement of the substrate relative to the projection system in use causes fluctuations in the position of a line of contact between a meniscus of the immersion liquid and the further surface; and the further surface has a static receding contact angle with respect to the immersion liquid of less than 90 degrees.

According to an aspect, there is provided a projection system for use with an immersion lithographic apparatus, wherein: the projection system is configured to project a patterned radiation beam through the projection system onto a target portion of a substrate; the projection system comprises: an exit surface through which to project the patterned radiation beam; and a further surface facing the liquid confinement structure; the further surface has a first static receding contact angle with respect to the immersion liquid; the exit surface has a second static receding contact angle with respect to the immersion liquid; and the first static receding contact angle is: greater than the second static receding contact angle; and less than 65 degrees.

According to an aspect, there is provided a last lens element for a projection system of an immersion lithographic apparatus, wherein: the projection system is configured to project a patterned radiation beam through the projection system onto a target portion of a substrate; the projection system comprises: an exit surface through which to project the patterned radiation beam; and a further surface facing the liquid confinement structure; the further surface has a first static receding contact angle with respect to the immersion liquid; the exit surface has a second static receding contact angle with respect to the immersion liquid; and the first static receding contact angle is: greater than the second static receding contact angle; and less than 65 degrees.

According to an aspect, there is provided a liquid control member, configured to be attached to, and conform in shape with, a portion of a projection system of an immersion lithographic apparatus, wherein: the projection system is configured to project a patterned radiation beam through the projection system onto a target portion of a substrate; the projection system comprises an exit surface through which to project the patterned radiation beam; the liquid control member comprises a further surface configured to face the liquid confinement structure when the liquid control member is attached to said portion of the projection system; the further surface has a first static receding contact angle with respect to the immersion liquid; the exit surface has a second static receding contact angle with respect to the immersion liquid; and the first static receding contact angle is: greater than the second static receding contact angle; and less than 65 degrees.

According to an aspect, there is provided a device manufacturing method, comprising: using a projection system to project a patterned radiation beam through the projection system onto a target portion of a substrate; and confining an immersion fluid in a space between the projection system and the substrate using a liquid confinement structure, the projection system comprising: an exit surface through which to project the patterned radiation beam; and a further surface facing the liquid confinement structure, wherein: the further surface has a first static receding contact angle with respect to the immersion liquid; the exit surface has a second static receding contact angle with respect to the immersion liquid; and the first static receding contact angle is: greater than the second static receding contact angle; and less than 65 degrees.

According to an aspect, there is provided a device manufacturing method, comprising: using a projection system to project a patterned radiation beam through the projection system onto a target portion of a substrate; and confining an immersion fluid in a space between the projection system and the substrate using a liquid confinement structure, the projection system comprising: an exit surface through which to project the patterned radiation beam; a further surface facing the liquid confinement structure,

wherein: movement of the substrate relative to the projection system causes fluctuations in the position of a line of contact between a meniscus of the immersion liquid and the further surface; and the further surface has a static receding contact angle with respect to the immersion liquid that is less than 90 degrees.

According to an aspect, there is provided a lithographic apparatus, comprising: a projection system configured to project a patterned radiation beam through an exit surface of the projection system onto a target portion of a substrate; and a liquid confinement structure configured to confine an immersion liquid in a space between the projection system and the substrate, wherein the projection system comprises a further surface facing the liquid confinement structure and having a static receding contact angle with respect to the immersion liquid that is a) at least 10 degrees greater than a static receding contact angle with respect to the immersion liquid of the exit surface, and b) less than 65 degrees

According to an aspect, there is provided a device manufacturing method, comprising: using a projection system to project a patterned radiation beam through an exit surface of the projection system onto a target portion of a substrate; and confining an immersion liquid in a space between the projection system and the substrate using a liquid confinement structure, wherein the projection system comprises a further surface facing the liquid confinement structure and having a static receding contact angle with respect to the immersion liquid that is a) at least 10 degrees greater than a static receding contact angle with respect to the immersion liquid of the exit surface, and b) less than 65 degrees.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 depicts a liquid supply system for use in a lithographic apparatus;

FIG. 3 is a side sectional view that depicts a further liquid supply system according to an embodiment;

FIG. 4 is a side sectional view of a lithographic apparatus in which a last lens element has an exit surface and a further surface;

FIG. 5 is a side sectional view of a lithographic apparatus in which a projection system comprises a passageway-former;

FIG. 6 is a side sectional view of a droplet on an inclined slope for illustrating static receding and static advancing contact angles;

FIG. 7 is a side sectional view of a portion of a further surface provided by a coating formed on the last lens element;

FIG. 8 is a side sectional view of a portion of a further surface provided by an uncoated liquid control member attached to the last lens element;

FIG. 9 is a side sectional view of a portion of a further surface provided by a coating formed on a liquid control member;

FIG. 10 is a side sectional view of a portion of a further surface provided by an uncoated portion of a passageway-former;

FIG. 11 is a side sectional view of a portion of a further surface provided by a coating formed on a passageway-former;

FIG. 12 depicts a frusto-conical liquid control member;

FIG. 13 depicts movement of immersion liquid over a surface and leaving behind of a film;

FIG. 14 depicts movement of a meniscus over a surface having a static receding contact angle of about 80 degrees;

FIG. 15 depicts movement of a meniscus over a surface having a static receding contact angle of close to zero degrees;

FIG. 16 depicts a convection current caused by movement of the immersion liquid over the further surface;

FIG. 17 depicts a convection current caused by an opposite movement of the immersion liquid over the further surface;

FIG. 18 is a graph showing the size of a negative performance effect originated from thermal loads on the projection system for different values of static receding contact angle, as observed experimentally;

FIG. 19 depicts an example configuration for a further surface of the last lens element and a liquid control surface of the confinement structure;

FIG. 20 depicts a further example configuration for a further surface of the last lens element and a liquid control surface of the confinement structure;

FIG. 21 depicts a further example configuration for a further surface of the last lens element and a liquid control surface of the confinement structure; and

FIG. 22 depicts an example configuration for a further surface of the last lens element and a liquid control surface of the confinement structure.

### DETAILED DESCRIPTION

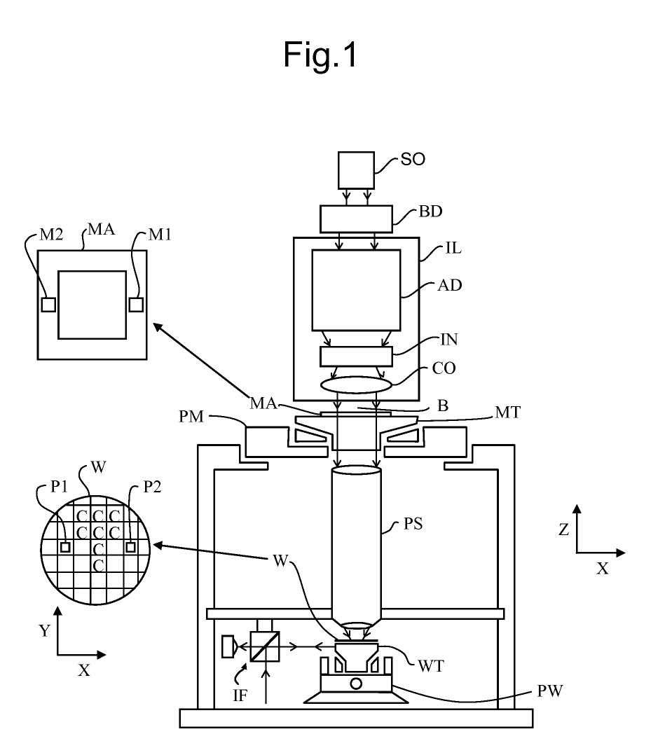

FIG. 1 schematically depicts a lithographic apparatus according to one embodiment of the invention. The apparatus includes an illumination system (illuminator) IL configured to condition a radiation beam B (e.g. UV radiation or any other suitable radiation), a mask support structure (e.g. a mask table) MT constructed to support a patterning device (e.g. a mask) MA and connected to a first positioning device PM configured to accurately position the patterning device in accordance with certain parameters. The apparatus also includes a substrate table (e.g. a wafer table) WT or “substrate support” constructed to hold a substrate (e.g. a resist-coated wafer) W and connected to a second positioning device PW configured to accurately position the substrate W in accordance with certain parameters. The apparatus further includes a projection system (e.g. a refractive projection lens system) PS configured to project a pattern imparted to the radiation beam B by patterning device MA onto a target portion C (e.g. including one or more dies) of the substrate W.

The illumination system may include various types of optical components, such as refractive, reflective, magnetic, electromagnetic, electrostatic or other types of optical components, or any combination thereof, for directing, shaping, or controlling radiation.

The mask support structure supports, i.e. bears the weight of, the patterning device. It holds the patterning device in a manner that depends on the orientation of the patterning device, the design of the lithographic apparatus, and other conditions, such as for example whether or not the patterning device is held in a vacuum environment. The mask support structure can use mechanical, vacuum, electrostatic or other clamping techniques to hold the patterning device. The mask support structure may be a frame or a table, for example, which may be fixed or movable as required. The mask support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section so as to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable mirror array of a type as referred to above, or employing a reflective mask).

The lithographic apparatus may be of a type having two (dual stage) or more object tables, at least one of which is a substrate table or “substrate support” (and/or two or more mask tables or “mask supports”). In such “multiple stage” machines the additional tables or supports may be used in parallel, or preparatory steps may be carried out on one or more tables or supports while one or more other tables or supports are being used for exposure.

The lithographic apparatus may also be of a type wherein at least a portion of the substrate may be covered by a liquid having a relatively high refractive index, e.g. water, so as to fill a space between the projection system and the substrate. An immersion liquid may also be applied to other spaces in the lithographic apparatus, for example, between the mask and the projection system. Immersion techniques can be used to increase the numerical aperture of projection systems. The term “immersion” as used herein does not mean that a structure, such as a substrate, must be submerged in liquid, but rather only means that a liquid is located between the projection system and the substrate during exposure. That is, a part of a surface of a last lens element is immersed in liquid. The immersed surface includes at least the part of the last lens surface through which the projection beam passes.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD including, for example, suitable directing mirrors and/or a beam expander. In other cases the source may be an integral part of the lithographic apparatus, for example when the source is a mercury lamp. The source SO and the illuminator IL, together with the beam delivery system BD if required, may be referred to as a radiation system.

The illuminator IL may include an adjuster AD configured to adjust the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may include various other components, such as an integrator IN and a condenser CO. The illuminator may be used to condition the radiation beam, to have a desired uniformity and intensity distribution in its cross-section.

The radiation beam B is incident on the patterning device (e.g., mask MA), which is held on the mask support structure (e.g., mask table MT), and is patterned by the patterning device MA. Having traversed the patterning device MA, the radiation beam B passes through the projection system PS, and through the liquid between the projection system PS and the substrate, which focus the beam onto a target portion C of the substrate W. With the aid of the second positioning device PW and position sensor IF (e.g. an interferometric device, linear encoder or capacitive sensor), the substrate table WT can be moved accurately, e.g. so as to position different target portions C in the path of the radiation beam B. Similarly, the first positioning device PM and another position sensor (which is not explicitly depicted in FIG. 1) can be used to accurately position the patterning device MA with respect to the path of the radiation beam B, e.g. after mechanical retrieval from a mask library, or during a scan. In general, movement of the mask table MT may be realized with the aid of a long-stroke module (coarse positioning) and a short-stroke module (fine positioning), which form part of the first positioning device PM. Similarly, movement of the substrate table WT or “substrate support” may be realized using a long-stroke module and a short-stroke module, which form part of the second positioner PW. In the case of a stepper (as opposed to a scanner) the mask table MT may be connected to a short-stroke actuator only, or may be fixed. Patterning device MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the mask alignment marks may be located between the dies.

Arrangements for providing liquid between a last lens element of the projection system PS and the substrate can be classed into three general categories. These are the bath immersion systems, the so-called localized immersion systems and the all-wet immersion systems. The present invention relates particularly to the localized immersion systems.

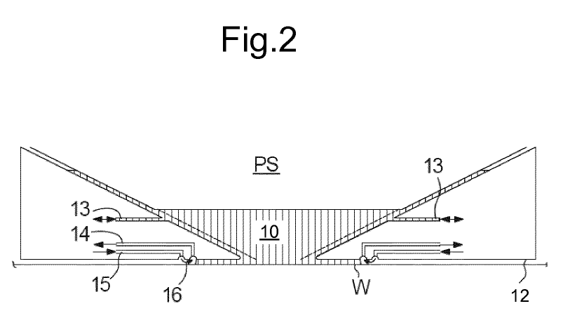

FIG. 2 schematically depicts a liquid confinement structure 12 of a localized immersion system. The liquid confinement structure extends along at least a part of a boundary of the immersion space 10 between the last lens element of the projection system PS and the substrate table WT or substrate W. In an embodiment, a seal is formed between the liquid confinement structure 12 and the surface of the substrate W. The purpose of the seal may be at least one of: confining liquid within the space 10 between the lens and the substrate W; and to seal a portion of a gap between the liquid confinement structure 12 and the facing surface of the substrate W (and/or substrate table) so gas does not ingress the space 10. Different sealing features may be used to achieve one or both of these functions. The seal may be a contactless seal such as a gas seal 16 (such a system with a gas seal is disclosed in European patent application publication no. EP-A-1,420,298 which is hereby incorporated by reference in its entirety) or a liquid seal which may be created through a supply of liquid through an opening in the underside of the liquid confinement structure 12, directly between the liquid confinement structure 12 and the facing surface. Such a liquid seal is disclosed in European Patent publication EP 1498778 A1 which is hereby incorporated by reference.

The liquid confinement structure 12 at least partly confines liquid in the space 10 between the last lens element of the projection system PS and the substrate W. The space 10 is at least partly formed by the liquid confinement structure 12 positioned below and surrounding the last lens element of the projection system PS. Liquid is brought into the space 10 below the projection system PS and within the liquid confinement structure 12 by opening 13. The liquid may be removed by opening 13. Whether liquid is brought into the space 10 or removed from the space 10 by the opening 13 may depend on the direction of movement of the substrate W and substrate table WT. In an embodiment of the type shown in FIG. 2, and in an embodiment according to any of the arrangements discussed below, the last lens element of the projection system can be frustoconically shaped. In such embodiments, the side surface of the last lens element is sloped downwardly towards an end surface of the last lens element and, in use, towards a substrate W. The end surface serves as an exit surface for the patterned radiation beam. The liquid confinement structure 12 may surround at least part of the side surface of the last lens element. The liquid confinement structure 12 may be shaped to cooperate with the last lens element so that a gap is formed between the side surface of the last lens element and an inner facing surface of the liquid confinement structure 12. During operation, liquid from the space 10 may penetrate a portion of the gap, so that a meniscus forms between the side surface of the last lens element and the inner facing surface of the liquid confinement structure 12.

The liquid may be confined in the space 10 by the gas seal 16 which, during use, is formed between the bottom of the liquid confinement structure 12 and the surface of the substrate W. The gas in the gas seal 16 is provided under pressure via gas inlet 15 to the gap between the liquid confinement structure 12 and substrate W. The gas is extracted via a channel associated with outlet 14. The overpressure on the gas inlet 15, vacuum level on the outlet 14 and geometry of the gap are arranged so that there is a high-velocity gas flow inwardly that confines the liquid. The force of the gas on the liquid between the liquid confinement structure 12 and the substrate W contains the liquid in the space 10. Such a system is disclosed in United States patent application publication no. US 2004-0207824, which is hereby incorporated by reference in its entirety.

In a localized immersion system, the substrate W is moved under the projection system PS and the liquid supply system. An edge of an object on a table WT may be moved under a liquid confinement structure 12. Such an object can be a substrate W which is to be imaged or a sensor on the substrate table (or on a measurement table) which is to be imaged. The object can be a dummy substrate (or so-called ‘closing plate’), which may be positioned in certain operations in place of a substrate W under the liquid supply system. When an edge of the substrate W (or other object) passes under the space 10 liquid may leak into the gap between the substrate W and substrate table WT.

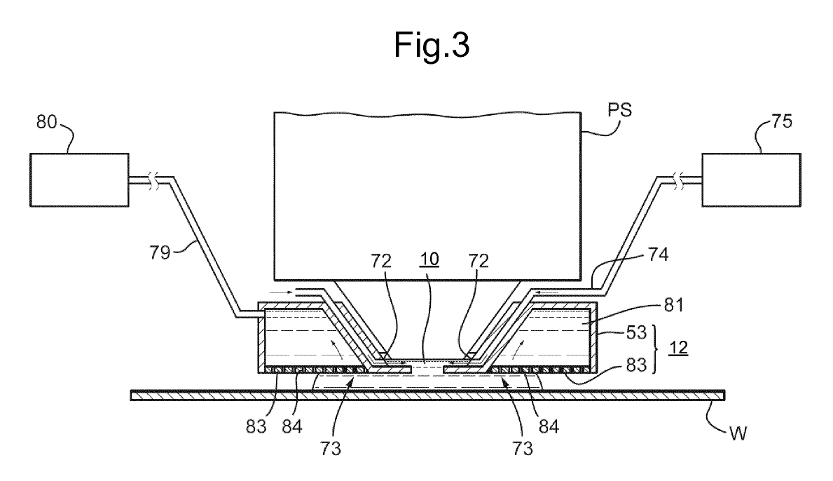

FIG. 3 is a side cross sectional view that depicts a further liquid supply system or fluid handling system according to an embodiment. The arrangement illustrated in FIG. 3 and described below may be applied to the lithographic apparatus described above and illustrated in FIG. 1. The liquid supply system is provided with a liquid confinement structure 12, which extends along at least a part of a boundary of the space 10 between the last lens element of the projection system PS and the substrate table WT or substrate W. The liquid confinement structure 12 at least partly confines liquid in the space 10 between the last lens element and the substrate W. The space 10 is at least partly formed by the liquid confinement structure 12 positioned below and surrounding the last lens element. In an embodiment, the liquid confinement structure 12 comprises a main body member 53 and a porous member 83. The porous member 83 may be planar and it may be plate shaped. The porous member 83 may be permeable to liquid and it may have a plurality of holes (i.e., openings or pores). In an embodiment, the porous member 83 is a mesh plate wherein numerous small holes 84 are formed in a mesh. Such a system is disclosed in United States patent application publication no. US 2010/0045949 A1, which is hereby incorporated by reference in its entirety.

The main body member 53 comprises supply ports 72, a flow plate and a recovery port 73. In operation the supply ports 72 supply the liquid to the space 10. The flow plate extends radially inwardly from the main body 53 separating the space into two volumes above the plate and below the plate. Within the plate is formed an aperture for the passage of: the patterned beam from the projection system PS to the substrate W; and the liquid from the supply ports 72 to beneath the plate and towards the recovery port 73. The recovery port 73 recovers the liquid from the space 10. The supply ports 72 are connected to a liquid supply apparatus 75 via passageways 74. The liquid supply apparatus 75 supplies the liquid to the supply ports 72. The liquid that is fed from the liquid supply apparatus 75 is supplied to each of the supply ports 72 through the corresponding passageway 74. The supply ports 72 are disposed in the vicinity of the optical path at prescribed positions of the main body member 53 that face the optical path. The recovery port 73 recovers the liquid from the space 10. The recovery port 73 is connected to a liquid recovery apparatus 80 via a passageway 79. The liquid recovery apparatus 80 comprises a vacuum system. The recovery apparatus is capable of recovering the liquid by suctioning it via the recovery port 73. The liquid recovery apparatus 80 recovers the liquid recovered via the recovery port 73 through the passageway 79. The porous member 83 is disposed in the recovery port 73.

In an embodiment, liquid is supplied from the supply ports 72 to the space 10. The pressure in a recovery chamber 81 in the liquid confinement structure 12 is adjusted to a negative pressure so as to recover the liquid via the holes 84 (i.e., the recovery port 73) of the porous member 83. Performing the liquid supply operation using the supply ports 72 and the liquid recovery operation through the porous member 83 ensures that liquid flows through the space 10. The liquid supply and recovery operations cause the space 10 within the liquid confinement structure 12 between the projection system PS and the facing surface (which includes the surface of the substrate W) to be filled with the liquid.

As mentioned in the introductory part of the description, it is known to apply a liquidphobic material to a portion of the projection system PS which contacts the immersion liquid in use. An example is disclosed in FIG. 8 of US 2012274912 A1 which is hereby incorporated by reference in its entirety. However, it has been observed that the effectiveness of the liquidphobic material in reducing heat load to the projection system degrades after a period of time.

A lithographic apparatus which at least partially addresses the unwanted applied heat load will now be described. In the following description the lithographic apparatus may be configured as described above with reference to FIG. 1. The lithographic apparatus comprises a liquid confinement structure 12. The liquid confinement structure 12 may form part of a fluid supply system or a liquid supply system as described above and illustrated in FIG. 2 or FIG. 3.

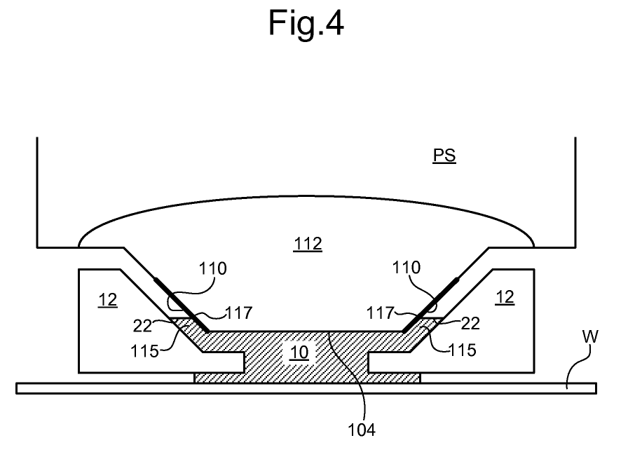

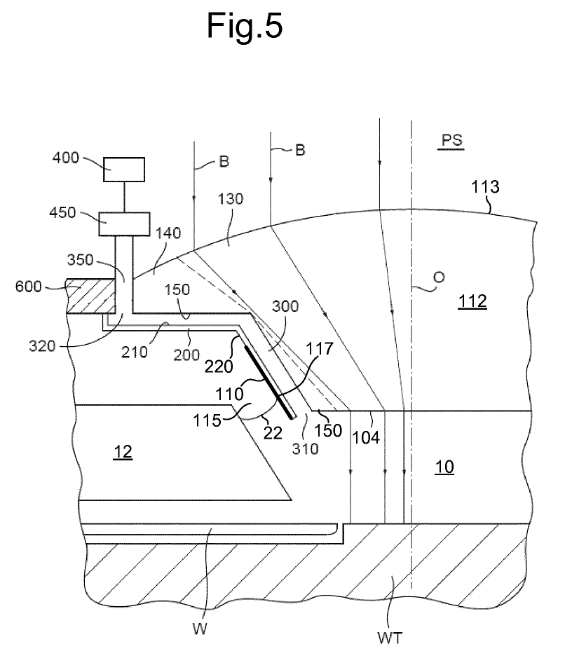

FIGS. 4 and 5 each depict a lithographic apparatus which may embody the invention. The lithographic apparatus comprises a projection system PS. In operation, the projection system PS projects a patterned radiation beam B through an exit surface 104 onto a target portion C of a substrate W. A liquid confinement structure 12 confines an immersion liquid to a space 10 between the projection system PS and a facing surface which may include a surface of the substrate W. The immersion liquid may be confined for example between a last lens element 112 and the substrate W. In an embodiment the liquid confinement structure 12 surrounds the space 10. The liquid confinement structure 12 may at least in part define the space 10. Additionally to the exit surface 104, the projection system PS comprises a further surface 110. The further surface 110 faces the liquid confinement structure 12. The further surface 110 thus faces and partly forms a gap 115 between the projection system PS and the liquid confinement structure 12. The further surface 110 may be at least partly formed of the sloped side surface of the last lens element 112.

In an embodiment, the liquid confinement structure 12 is configured so that movement of the substrate W (and therefore also of the substrate table WT) relative to the projection system PS in use causes fluctuations in the position of a line of contact 117 between a meniscus 22 of the immersion liquid and the further surface 110 in the gap 115.

FIG. 4 depicts an arrangement in which the further surface 110 is formed as an integral part of the last lens element 112 or as a coating or structure formed on the last lens element 112. FIG. 5 depicts an arrangement in which the further surface 110 is formed as an integral part of a passageway-former 200 or as a coating or structure formed on the passageway-former 200.

A portion of the body of the last lens element 112 through which the patterned radiation beam B passes may be referred to as an optically active part 130. In the example of FIG. 5, the optically active part 130 is the part enclosed by the top surface 113, the exit surface 104 and the dashed lines.

Part of the last lens element 112 radially outward of the optically active part 130 is a non-optically active part 140 of the body of the last lens element 112. The patterned radiation beam B does not pass through the non-optically active part 140 of the body of the last lens element 112. A part of the bottom surface through which none of the patterned radiation beam B passes may be referred to as a non-optically active bottom surface 150 of the last lens element 112. Together the exit surface 104 and non-optically active bottom surface 150 make up an exposed bottom surface of the last lens element 112. The exposed bottom surface of the last lens element 112 is exposed (or bare) in that it is exposed to the external environment. The exposed bottom surface of the last lens element 112 is an uncovered (or naked) surface in that it is uncovered by components of the projection system PS for example by a last lens element support 600.

Alternatively or additionally, part of the bottom surface of the last lens element 112 might not be exposed to the external environment. Part of the bottom surface may be covered for example by a support component. The exposed bottom surface of the last lens element 112 is not covered by a last lens element support 600 of the projection system PS.

In an embodiment, the liquid in the space 10 is in contact with a lowest part of the exposed bottom surface of the last lens element 112. The liquid in the space 10 is in contact with the entire exit surface 104. The liquid in the space 10 is in contact with a lowest portion of the non-optically active bottom surface 150.

In the embodiment of FIG. 5 a passageway-former 200 is positioned between the projection system PS and the liquid confinement structure 12. The passageway-former 200 has an outer former surface 220 and an inner former surface 210. The outer former surface 220 faces radially outwards and/or downwards, relative for example to an optical axis 0 of the projection system PS passing through the exit surface 104. The inner former surface 210 faces radially inwards and/or upwards, relative for example to an optical axis 0 of the projection system PS passing through the exit surface 104. At least a portion of the outer former surface 220 faces the liquid confinement structure 12. At least a portion of the inner former surface 210 faces the last lens element 112. A meniscus of liquid 22 extends between the liquid confinement structure 12 and the outer former surface 220. The meniscus 22 defines a part of the boundary of the space 10.

The passageway-former 200 extends, in plan, all the way around at least a portion of the last lens element 112. In an embodiment the passageway-former 200 is co-axial with the last lens element 112. The passageway-former 200 may be seen as a ‘cup’ with respect to the last lens element 112.

The passageway-former 200 is positioned between the last lens element 12 and the liquid confinement structure 12 in such a way that a passageway 300 is defined between the passageway-former 200 and the last lens element 112. The passageway 300 is defined at least in part between the inner former surface 210 and the last lens element 112. The passageway 300 has an opening 310. The opening 310 is at the radially innermost end of the passageway 300 relative for example to an optical axis 0 of the projection system PS passing through the exit surface 104. The opening 310 brings the passageway 300 into liquid communication with the space 10.

In an embodiment the passageway 300 is, in use, filled with liquid. The presence of liquid in the passageway 300 means that any heat load applied to the passageway-former 200 radially outward of the meniscus 22 imparts a lower heat load to the last lens element 112 than would be the case in the absence of the passageway-former 200 and passageway 300. Such a heat load could be applied to the passageway-former 200, for example, by the presence of a droplet or film of liquid on the outer former surface 220 of the passageway-former 200.

If the whole of passageway 300 is filled with liquid, there will be no meniscus in the passageway 300. The presence of a meniscus in the passageway 300 might result in a heat load being applied to the last lens element 112 due to evaporation of liquid at the meniscus.

In an embodiment the passageway 300 is constructed and configured such that, in use, it is filled with liquid from the space 10 by capillary action. In an embodiment the passageway 300 is sized to allow capillary action to drawn (or suck) liquid out of the immersion space 10 in a radially outwards direction (i.e. relative to the path of the projection beam through the projection system). In an embodiment, the passageway 300 has a minimum dimension in a cross-section of 0.75 mm or less. This dimension allows sufficient capillary force to be generated. Liquid removed from the space 10 by capillary action may exit the passageway 300 through a further opening 320.

In an embodiment a further opening controller 400 may be provided. The further opening controller 400 controls a liquid supply and/or recovery system 450. The liquid supply and/or recovery system 450 supplies and/or recovers liquid from the further opening 320. One or more of the further opening controller 400, the liquid supply system and the liquid recovery system may be removed from the projection system PS. They may be housed in a fluid cabinet, separate from projection system PS or even the lithographic apparatus. The further opening controller 400 is fluidly connected to at least one of the liquid supply system and the liquid recovery system. The liquid supply and/or recovery system 450 may apply an under-pressure to the further opening 320. The under-pressure may be used in addition to capillary forces to remove liquid from the immersion space 10. Alternatively the under-pressure applied by the liquid supply and/or recovery system 300 may be used as an alternative to capillary action to remove liquid through the passageway 300 from the immersion space 10. The under pressure applied to the liquid may be a force larger than the capillary force which would be applied, such that the effective capillary force is in comparison to the under pressure force negligible.

The further opening controller 400 may be adapted to control supply and/or recovery of liquid through the further opening 320 continuously or discontinuously, for example in a periodic fashion. For example, the further opening controller 400 may be adapted periodically to replenish liquid in the passageway 300. In order to avoid vibrations due to liquid flow in the passageway 300 deleteriously effecting imaging of a substrate W, the further opening controller 400 may be adapted to replenish liquid in the passageway 300 between imaging of substrates W or between imaging a lot of substrates. In an embodiment, the further opening controller 400 may be adapted to replenish liquid in the passageway 300 periodically, for example once every few hours or once every day. Replenishing liquid in the passageway 300 helps in maintaining the liquid in the passageway 300 at a constant temperature. Replenishing liquid in the passageway 300 also helps to prevent growth of organics (such as algae) in the liquid in the passageway 300 which might otherwise be a source of contamination.

The liquid supply and/or recovery unit 450 may be used to supply liquid to the further opening 320, through the passageway 300, out of the passageway 300, through opening 310 and into the space 10. The liquid supply and/or recovery unit 450 may be used to recover liquid from the space 10, through opening 310, through passageway 300 and out of passageway 300 through the further opening 320. In an embodiment the further opening controller 400 may be used to change a liquid flow pattern in the space 10. For example, the further opening controller 400 may induce a flow of liquid across the space 10 from one side of the space 10 to the other side of the space 10. This may be achieved by providing two or more passageways 300 through which flow of liquid is individually controllable by the further opening controller 400. For example, a first passageway 300 could provide a flow of liquid into the immersion space 10 through opening 310. A second passageway 300, for example on the opposite side of the space 10 to the first passageway 300, could be used to remove liquid from the space 10 through opening 310. In this way, a flow of liquid across the space 10 from side of the space 10 to the other side of the space 10 can be achieved. In an arrangement the liquid flow through the passageways 300 can be integrated into the flow path of the body of liquid in the space 10. This flow path may be across the space 10 perpendicular to the scanning movement of the substrate table WT during an exposure.

In the embodiment of FIG. 5 the passageway-former 200 is separate from the last lens element 112. That is, the passageway-former 200 is non-integral with the last lens element 112. The passageway 300 is formed between the inner former surface 210 of the passageway-former 200 and the last lens element 112.

In an embodiment the passageway-former 200 is shaped such that its distance from the exposed bottom surface of the last lens element 112 is substantially constant. The shape, in cross-section, of the inner former surface 210 is substantially the same as that of the corresponding exposed bottom surface of the last lens element 112. In an embodiment the passageway-former 200 is of constant thickness (for example about 200 μm thick). In other embodiments the passageway-former 200 is shaped such that its distance from the exposed bottom surface of the last lens element 112 varies as a function of position, for example continuously narrowing or widening in a downwards direction, or forming microfluidic structures. In an embodiment, the variation of the distance as a function of position may improve flow stability. In embodiments the passageway-former 200 may be shaped so that its distance from the exposed bottom surface of the last lens element 112 is about 1mm on average.

In an embodiment the passageway-former 200 may be made of a material with a high thermal conductivity. The material of the passageway-former 200 may have a thermal conductivity of greater than 150 Wm⁻¹K⁻¹, optionally greater than 250 Wm⁻¹K⁻¹. For example, the material of the passageway-former 200 may be made of (coated) aluminum alloy, which can have a thermal conductivity of about 160 Wm⁻¹K⁻¹. Alternatively, the material of the passageway-former 200 may be made of a metal, such as silver, or of diamond. Any thermal load applied locally to the passageway-former 200 in this embodiment is quickly dissipated by thermal conduction in all directions in the passageway-former 200 including in the radial direction. Thus, the heat load is dissipated. As a result, any thermal load which reaches the optically active part 130 of the last lens element 112 will be less localized and any resulting aberrations or focus errors will be lower.

In an alternative embodiment the material of the passageway-former 200 has a low thermal conductivity. In having a low thermal conductivity, the passageway-former 200 may insulate the last lens element 112. In one embodiment the material of the passageway-former 200 has a thermal conductivity of less than 1 Wm⁻¹K⁻¹. A typical thermal conductivity for the last lens element 112 may be about 1.4 Wm⁻¹K⁻¹. The material of the passageway-former 200 may be a ceramic or a plastic.

In other embodiments the thermal conductivity of the passageway-former 200 has an intermediate thermal conductivity, between 1 Wm⁻¹K⁻¹ and 150 Wm⁻¹K⁻¹.

In an embodiment, the passageway-former 200 may have on its outer former surface 220 a coating with a high thermal conductivity. Such a coating may have a thermal conductivity of greater than 150 Wm⁻¹K⁻¹, optionally greater than 250 Wm⁻¹K⁻¹. Such a coating functions in the same way as if the passageway-former 200 itself is made of a material with a high thermal conductivity, as described above.

The passageway-former 200 may be supported between the last lens element 112 and the liquid confinement structure 12 in any way. In the embodiment of FIG. 5, the passageway-former 200 forms part of the projection system PS. In particular, the passageway-former 200 is attached to a last lens element support 600 of the projection system PS. The last lens element support 600 is a frame of the projection system PS. The last lens element support 600 supports the last lens element 112. In the embodiment shown the passageway-former 200 is supported at its radially outermost end by the last lens element support 600. In the embodiment of FIG. 5 the further opening 320 is connected to the liquid supply and/or receiving system 300 via a connecting passageway 350 formed between the last lens element support 600 and the last lens element 112. The connecting passageway 350 may be located at one or more discrete locations. In an embodiment, the connecting passageway 350 does not extend entirely around the last lens element 112. There may be more than one connecting passageway 350, for example radially spaced uniformly or non-uniformly around the last lens element 112.

Alternatively or additionally to being supported by the last lens element support 600, the liquid supply and/or recovery system 450 applies an under pressure between the passageway-former 200 and the exposed bottom surface of the last lens element 112. The under pressure is an under pressure above the passageway-former 200 compared to an ambient pressure underneath the passageway-former 200. The presence of the under pressure applies an attractive force to the passageway-former 200 towards the projection system PS thereby to hold the passageway-former 200 to the last lens element 112.

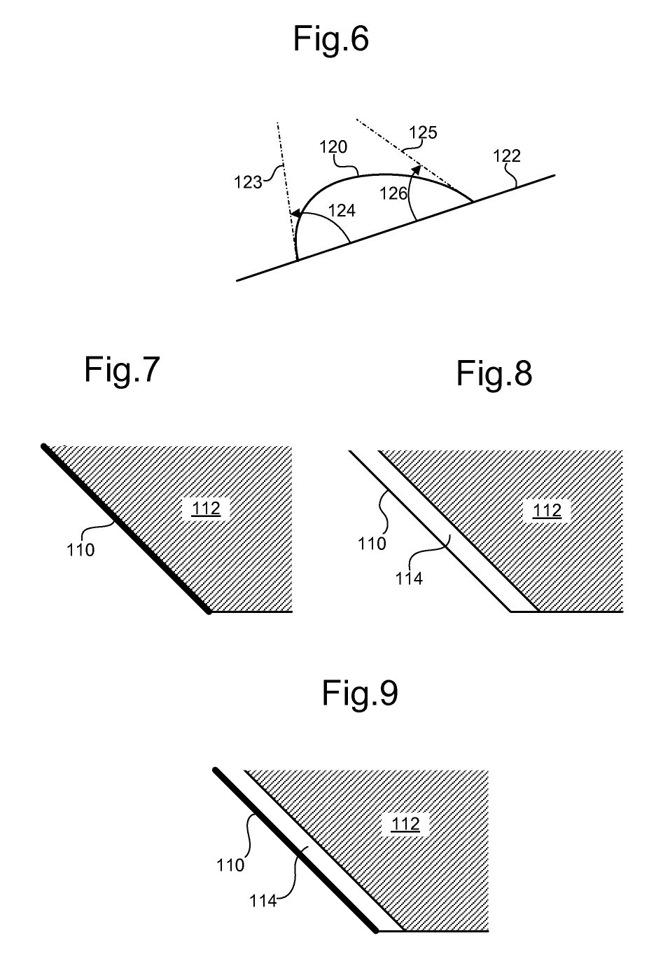

The concept of a static receding contact angle is known in the art. Receding and advancing contact angles are particularly relevant to dynamic properties of a liquid in contact with a surface. The contact angle references the angle of the gas liquid interface of a liquid body, alternatively referred to as a meniscus, at the point the interface intersects the surface on which the liquid body is located. In a dynamic context, when the body of liquid is moving over the surface, the contact angle at a leading edge of the moving body may be referred to as an advancing contact angle. The contact angle at a trailing edge of the moving body may be referred to as a receding contact angle. A static receding contact angle is the receding contact angle of a body of liquid to which a force has been applied which is just insufficient to cause motion of the body of liquid. FIG. 6 illustrates the principle. Here a body of liquid 120 has been placed on a surface 122. The surface 122 is then inclined gradually until the surface 122 is at an angle to the horizontal which is just insufficient to cause motion of the body of liquid 122 down the slope. If the surface 122 were to be inclined any further the body of liquid 122 would start to move. In this state, the contact angle 124 at the leading edge is the static advancing contact angle. The static advancing contact angle is defined as the angle between the surface 122 and the tangent 123 to the meniscus of the body of liquid at the surface 122. The contact angle 126 at the trailing edge is the static receding contact angle. The static receding contact angle is defined as the angle between the surface 122 and the tangent 125 to the body of liquid at the surface 122. The static receding contact can thus be measured for any combination of surface 122, liquid 120 and surrounding atmosphere.

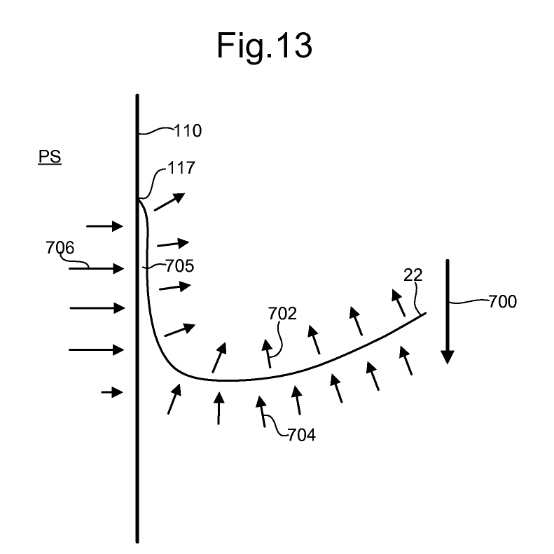

The inventors have recognized that the static receding contact angle is important for determining the behavior of immersion liquid moving (sloshing) within the gap 115 between the liquid confinement structure 12 and the projection system PS. The static receding contact angle determines the theoretical maximum speed of movement of the line of contact 117 between the meniscus 22 of the immersion liquid and a portion of the projection system PS with which the line of contact 117 is in contact. According to embodiments, this speed is adapted by providing the further surface 110 of the projection system PS with an appropriately selected static receding contact angle. Increasing the static receding contact angle increases the theoretical maximum speed of movement. Increasing the theoretical maximum speed of movement makes it less likely that a film of immersion liquid, or droplets, will be left behind on the further surface 110 due to fluctuations in the position of the line of contact 117 in the gap 115. Where a film or droplets is/are left behind the size of the film will be lower or the amount of droplets will be less. Thus, thermal load on the projection system PS due to evaporation of immersion liquid left behind on the further surface 110 will tend to be reduced by arranging for the static receding contact angle of the further surface 110 to be relatively high. The thermal effects of leaving behind a film 705 of immersion liquid are depicted schematically in FIG. 13. A meniscus 22 is shown moving downwards (arrow 700) over the further surface 110 of the projection system PS. The speed of movement of the meniscus 22 is greater than the theoretical maximum speed of movement of the line of contact 117, which results in a thin film 705 of immersion liquid being left behind the moving body of immersion liquid. Heat loss to the atmosphere above the meniscus 22, due to evaporation, is indicated by arrows 702. The temperature gradient caused by the heat loss causes heat to flow towards the meniscus 22 from the bulk of the liquid (arrows 704) and from the projection system PS (arrows 706). Evaporation from the film 705 applies relatively high cooling to the projection system PS due to the close proximity of the projection system PS to the meniscus 22 in the region of the film 705. Please note that the further surface 110 is depicted vertically for simplicity only and may be oriented differently in practice (as shown in other embodiments).

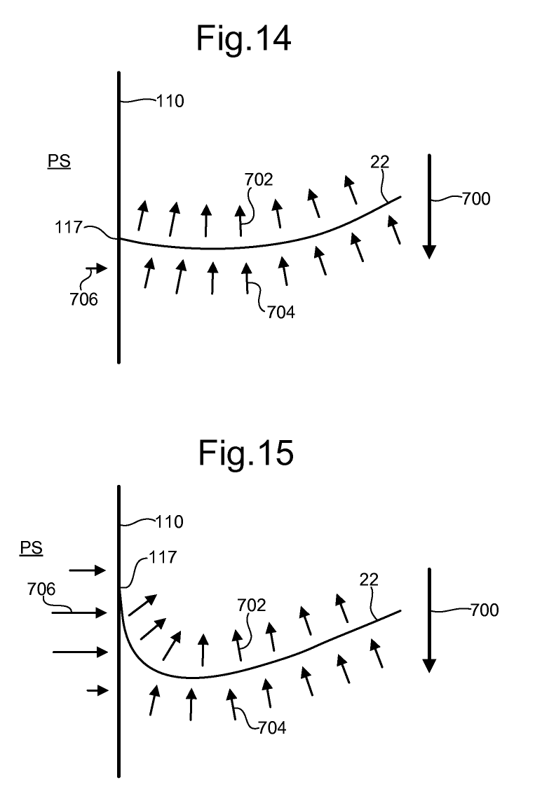

Furthermore, the inventors have recognized that for lower static receding contact angles, the meniscus formed when the immersion liquid is receding (e.g. moving downwards along the gap 115) will tend to be flatter than for higher static receding contact angles (even if a film of liquid is not actually left being entirely, in the sense discussed above with reference to FIG. 13). Evaporation from the flatter meniscus will tend to apply a higher level of cooling to the projection system PS. The effect is illustrated schematically in FIGS. 14 and 15. FIGS. 14 and 15 show a schematic meniscus 22 moving downwards (arrow 700) over the further surface 110 of the projection system PS. In FIG. 14, the further surface 110 has a static receding contact angle of about 80 degrees. In FIG. 15, the further surface 110 has a static receding contact angle of close to 0 degrees. Heat loss to the atmosphere above the meniscus 22, due to evaporation, is indicated by arrows 702. The temperature gradient caused by the heat loss causes heat to flow towards the meniscus 22 from the bulk of the liquid (arrows 704) and from the projection system PS (arrows 706). The flatter form adopted by the meniscus on the trailing side 708 of the immersion liquid in FIG. 15, relative to FIG. 14, causes greater cooling to be applied to the projection system PS in the arrangement of FIG. 15 relative to the arrangement of FIG. 14 (illustrated schematically by the larger arrows 706 in FIG. 15 relative to FIG. 14). Please note that the further surface 110 is depicted vertically for simplicity only and may be oriented differently in practice (as shown in other embodiments).

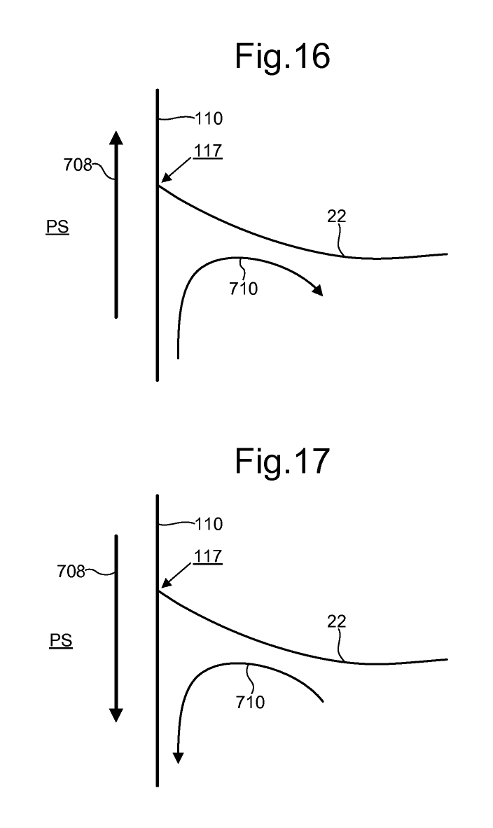

Furthermore, the inventors have recognized that allowing sloshing to occur relatively freely, by providing a further surface 110 having a relatively high static receding contact angle, leads to significant convection within the immersion liquid. This effect is illustrated schematically in FIGS. 16 and 17. Relative movement between the further surface 110 and the meniscus 22 is indicated by arrows 708 (the further surface 110 is moving upwards relative to the meniscus 22 in FIG. 16 and downwards relative to the meniscus 22 in FIG. 17). Friction between the further surface 110 and the immersion liquid contributes to convective currents in the immersion fluid (indicated schematically by arrows 710). It is thought that convention may decrease deleterious heat transfer between the immersion liquid and the projection system PS, thereby improving performance.

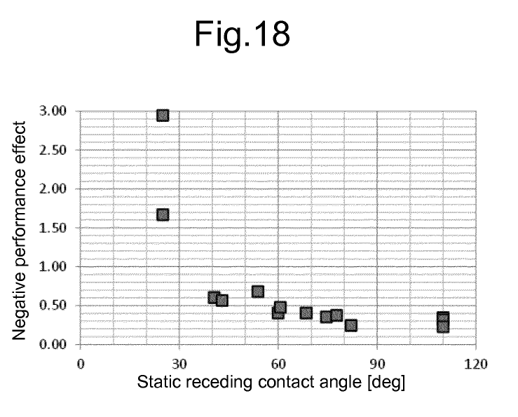

FIG. 18 shows the results of experimental measurements of the effects of thermal loads on the projection system PS (vertical axis) for different values of static receding contact angle (horizontal axis) of the further surface 110. Higher values on the vertical axis indicate greater thermal load on the projection system PS. Contrary to simple theoretical models which predict a sudden rise in the thermal load at static receding contact angles in the region of 50 degrees, the experimental measurements show that thermal load remains low down to about 30 degrees, or even lower.

The inventors have thus achieved a more detailed understanding than was available previously about how the shape and movement of the meniscus leads to heat load being applied to the projection system PS. As a result of this understanding, the inventors have recognized that designing surfaces so that their static contact angle is greater than 90 degrees with respect to the immersion liquid (i.e. hydrophobic where the immersion liquid is water) is not the optimal approach. Instead, reference should be made firstly to the static receding contact angle rather than the static contact angle. The static receding contact angle provides more information about the expected dynamic behavior of the immersion liquid than the static contact angle. Furthermore, the inventors have found that it is possible to achieve satisfactory performance for a range of static receding contact angles less than 90 degrees.

Recognizing that it is not necessary for the further surface 110 to have a static receding contact angle of more than 90 degrees greatly widens the range of materials that can be used to implement the further surface 110. Materials which have higher mechanical and/or chemical robustness than materials having a static receding contact angle of greater than 90 degrees (e.g. hydrophobic surfaces in the case where the immersion liquid is water) can be used, thereby increasing longevity of the further surface 110. The need for regular servicing of the further surface 110 can therefore be reduced relative to alternative approaches that use a further surface 110 having a static receding contact angle of more than 90 degrees.

Furthermore, configuring the further surface 110 to have a static receding contact angle of less than 90 degrees can reduce the risk of localized heat loads arising at defects in the further surface 110. If the further surface 110 were to have a higher static receding contact angle, the difference is static receding contact angle in the region of the defect compared with the surrounding regions is likely to be larger. Typically, defects tend to have relatively low static receding contact angles, thereby attracting immersion liquid. A larger difference in static receding contact angle increases the risk of liquid being retained at the defect in a localized pool. Such localized pooling of immersion liquid can lead to localized heat loads.

In an embodiment, the further surface 110 has a first static receding contact angle with respect to the immersion liquid and the exit surface 104 has a second static receding contact angle with respect to the immersion liquid. In an embodiment, the first static receding contact angle is greater than the second static receding contact angle, optionally at least 10 degrees greater. The exit surface 104 is typically formed from a material having a very low static receding contact angle. For example, where the exit surface 104 is a bare surface of a last lens element 112 formed from quartz glass, the static receding contact angle of the exit surface 104 will be about 25 degrees. In this case, and in other embodiments, the further surface 110 will be arranged to have a static receding contact angle greater than 25 degrees, optionally greater than 30 degrees, optionally greater than 35 degrees, optionally greater than 40 degrees, optionally greater than 45 degrees, optionally greater than 50 degrees, optionally greater than 55 degrees, optionally greater than 60 degrees, optionally greater than 65 degrees, optionally greater than 70 degrees, optionally greater than 75 degrees, optionally greater than 80 degrees, optionally greater than 85 degrees. Additionally, the static receding contact angle of the further surface 110 with respect to the immersion liquid is less than 90 degrees. Static receding contact angles within these ranges have been found to provide adequate limitation of evaporative heat loads during typical movements of the immersion liquid in the gap 115.

In an embodiment, the further surface 110 has a static receding contact angle with respect to the immersion liquid that is less than 70 degrees, optionally less than 65 degrees. Various materials having high mechanical and chemical robustness are available which provide static receding contact angles of less than 70 degrees or less than 65 degrees.

In an embodiment, a lower limit of the static receding contact angle is defined by the expected maximum speed of movement of the immersion liquid in the gap 115 between the confinement structure 12 and the projection system PS. The static receding contact angle is selected to be high enough so that movement of the line of contact 117 between the meniscus 22 and the projection system PS can be fast enough to keep up with the maximum speed of movement of the body of immersion liquid in the gap 115. If the line of contact 117 can keep up with the speed of the body of immersion liquid, little or no film or droplets of the immersion liquid will be left behind on the projection system PS.

In an embodiment, the further surface 110 has a static receding contact angle with respect to the immersion liquid of greater than 30 degrees, for example between 30 degrees and 90 degrees, optionally between 30 degrees and 70 degrees, optionally between 30 degrees and 65 degrees. Arranging for the static receding contact angle to be greater than 30 degrees reduces film formation at least for immersion liquid moving at moderate speeds, for example speeds of the order of several centimeters per second or less. Metal foils comprising or consisting of titanium or nickel can have static receding contacts angles in the range of 30-50 degrees for example.

In an embodiment, the further surface 110 has a static receding contact angle with respect to the immersion liquid of greater than 50 degrees, for example between 50 degrees and 90 degrees, optionally between 50 degrees and 70 degrees, optionally between 50 degrees and 65 degrees. Arranging for the static receding contact angle to be greater than 50 degrees reduces film formation for immersion liquid moving at relative fast speeds, for example at speeds of up to ten centimeters per second. Non-fluoride plastics such as PEEK and PET are examples of materials which have static receding contact angles in the range of 50 degrees to 65 degrees. PEEK has a static receding contact angle of about 55 degrees. PET has a static receding contact angle of about 60 degrees.

In an embodiment, the further surface 110 has a static receding contact angle with respect to the immersion liquid of greater than 55 degrees, for example between 55 degrees and 90 degrees, optionally between 55 degrees and 70 degrees, optionally between 55 degrees and 65 degrees. Arranging for the static receding contact angle to be in the range of 55 degrees to 70 degrees, or 55 degrees to 65 degrees, provides a particularly desirable balance of properties. Film formation on the projection system PS is reduced for a wide range of immersion liquid movement speeds.

Not being restricted to materials having static receding contact angles greater than 90 degrees facilitates selection of materials for the further surface 110 which have desirable properties, such as: low cost, good thermal properties (e.g. particularly high conductivity, to spread out heat load, or particularly low conductivity, to insulate), good mechanical properties, hard-wearing, easily manufactured, and transparency to UV light (which reduces degradation of the material due to stray UV light).

Palladium (having a static receding contact angle of about 60 degrees) is particularly hard-wearing. In an embodiment, the further surface 110 may comprise one or more of the following: a palladium coated metal, palladium coated copper, palladium coated titanium, palladium coated aluminum. A further surface 110 formed in this way will be hard-wearing.

In an embodiment, the further surface 110 may comprise a non-fluoride plastic such as PEEK or PET. A further surface 110 formed in this way will be easy to manufacture.

In an embodiment, the further surface 110 comprises a polyimide film such as poly (4,4′-oxydiphenylene-pyromellitimide) (Kapton). Kapton has a static receding contact angle of about 65 degrees.

The abovementioned materials for the further surface 110 are exemplary only. Some of the materials may not be suitable for use in all commercial lithographic processes, for example where contamination from leakage of the material would be undesirable, or where the lifetime of the material would not be sufficient. However, references to this range of materials is intended to assist in demonstrating the variety of materials which may be used (in a non-limited list).

In embodiments, examples of which are shown in FIGS. 7, 9 and 11, the further surface 110 comprises a surface of a coating.

In embodiments, an example of which is shown in FIG. 5, the further surface 110 is provided on a passageway-former 200.

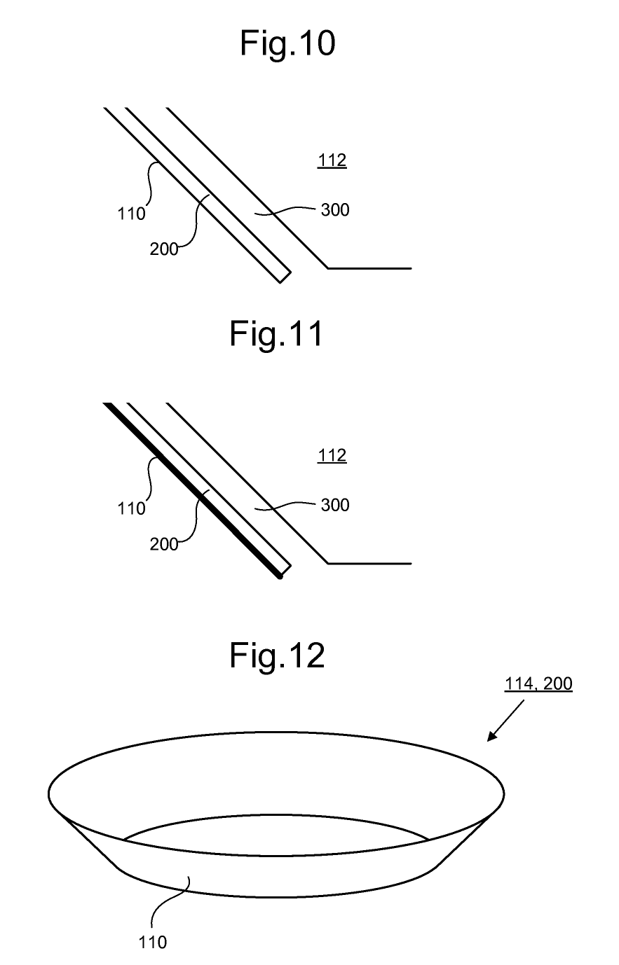

In embodiments, examples of which are shown in FIGS. 8-11, the further surface 110 is provided on a liquid control member 114. The liquid control member 114 is attached to a portion of the projection system PS. The liquid control member 114 conforms in shape with the portion of the projection system PS to which the liquid control member 114 is attached. In an embodiment, the liquid control member 114 is attached to the passageway-former 200. In an embodiment, the liquid control member 114 is attached to the last lens element 112. In an embodiment the liquid control member 114 is preformed. A preformed liquid control member 114 is not a coating for example. In an embodiment the liquid control member 114 is attached to the portion of the projection system PS using an adhesive. The liquid control member 114 may be a self-adhesive planar member (and may be referred to as a ‘sticker’). The liquid control member may be resilient such that as a planar surface it can be conformed and adhered to a curved surface of the projection system. The liquid control member 114 may be a rigid element. The liquid control member 114 may be attached to the portion of the projection system PS by applying an adhesive to one or both of the liquid control member 114 and the portion of the projection system PS. The adhesive may or may not be considered as part of the liquid control member 114. The adhesive has a different composition from the rest of the liquid control member 114.

In an embodiment the liquid control member 114 comprises a sloped surface angled obliquely to the exit surface 104 when attached to the projection system PS. In an embodiment the liquid control member 114 comprises a frusto-conical portion when attached to the projection system PS. Alternatively or additionally, the liquid control member 114 comprises a planar portion parallel to the exit surface 104 when attached to the projection system PS. The liquid control member 114 conforms to the shape of the surface to which it is secured. The liquid control member 114 may thus conform in shape with a portion of the last lens element 112 that is frusto-conical or with a portion of the passageway-former 200 that is frusto-conical. An example of a frusto-conical liquid control member 114 is shown in FIG. 12.

In an embodiment, the liquid control member 114 conforms in shape with the portion of the projection system PS to which the liquid control member 114 is to be attached before attachment.

In embodiments the further surface 110 comprises or consists of a sloped surface angled obliquely to the exit surface 104. The further surface 110 may therefore comprise a frusto-conical form or consist of a frusto-conical form, but other shapes are also possible which comprise or have a sloped surface angled obliquely to the exit surface 104. The further surface 110 may additionally comprise a planar surface. The planar surface can be parallel to the exit surface 104. Alternatively, the further surface 110 may consist of a planar surface, which can be parallel to the exit surface 104.

In the above embodiments, reference has been made exclusively to properties of a surface (the further surface 110) provided on the projection system PS. Other surfaces may also contribute to reducing heat load on the projection system PS. In an embodiment, the liquid confinement structure 12 comprises a liquid control surface 720 facing the projection system PS. The liquid control surface 720 may be formed using one of the configurations discussed above for the further surface 110. The liquid control surface 720 may therefore have any of the static receding contact angles with respect to the immersion liquid discussed above for the further surface 110. Configuring the liquid control surface 720 in this way makes it possible for the meniscus 22 to move freely over the liquid control surface 720 without film or droplet formation on the liquid control surface 720.

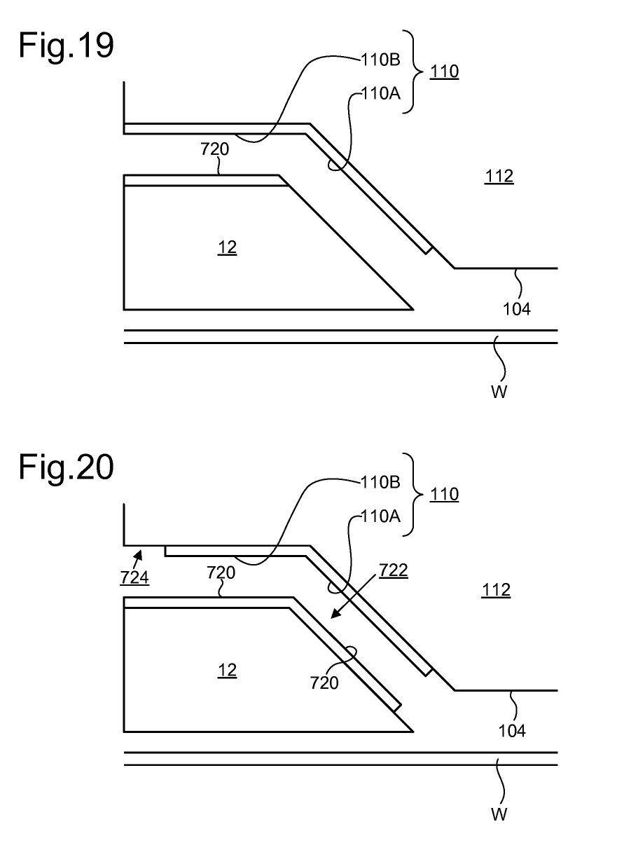

FIGS. 19-22 depict non-limiting example configurations for the further surface 110 and the liquid control surface 720. The surfaces 110 and 720 can be formed using any of the techniques shown above, for example as a surface of a coating applied to the projection system PS or liquid confinement structure 12, as a surface of a liquid control member attached (e.g. adhered) to the projection system PS or liquid confinement structure 12, or as a coating applied to a liquid control member attached (e.g. adhered) to the projection system PS or liquid confinement structure 12. In the examples of FIGS. 19-22, both of a further surface 110 and a liquid control surface 720 are provided. Each of the examples may also be provided in a form where only the further surface 110 is provided as shown, with no modifications being made to any of the surface of the liquid confinement structure 12 that faces the projection system PS.

In FIG. 19, an arrangement is depicted in which the further surface 110 comprises a frusto-conical part 110A and a planar part 110B. The planar part 110B is parallel to the exit surface 104. In this embodiment, the liquid control surface 720 is provided only on a portion of the liquid confinement structure 12 that faces the planar part 110B of the further surface 110. In this particular embodiment, the planar part 110B covers all of a planar portion of the last lens element 112 facing the liquid confinement structure 12. In the example shown, the frusto-conical part 110A covers less than all of a frusto-conical part of the last lens element 112. In a modified version of this embodiment the further surface 110 covers all of the frusto-conical part of the last lens element 112.

In FIG. 20, an arrangement is depicted which is the same as that of FIG. 19 except that: 1) an upper portion 722 of an inwardly facing part of the liquid confinement structure 12 is provided with the liquid control surface 720; and/or 2) the planar part 110B covers all of the planar portion of the last lens element 112 except a radially outer portion 724.

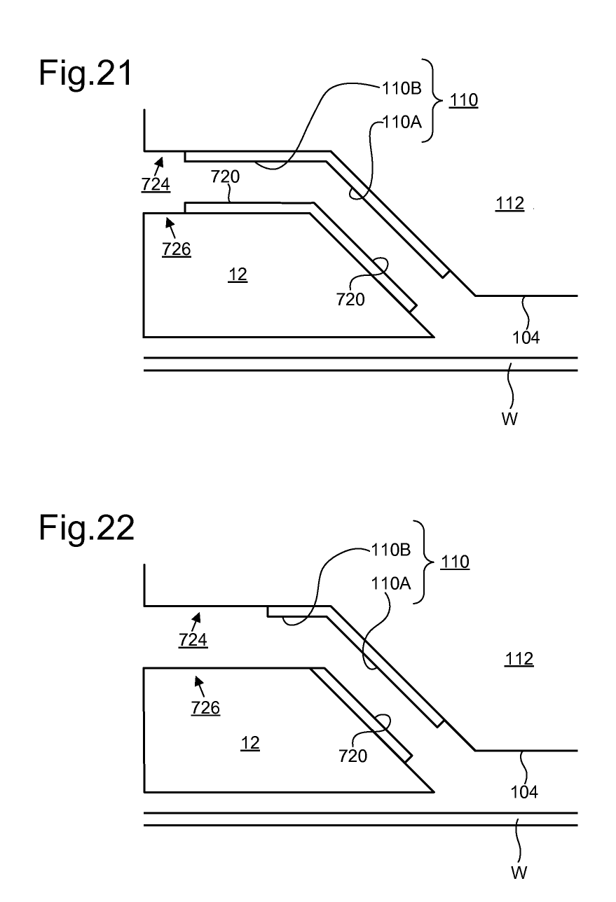

In FIG. 21, an arrangement is depicted which is the same as that of FIG. 20 except that the liquid control surface 720 covers all of the portion of the liquid confinement structure 12 that faces the planar part 110B of the further surface 110 except for a radially outer portion 726.

In FIG. 22, an arrangement is depicted which is the same as that of FIG. 21 except that the liquid control surface 720 does not cover any of the portion of the liquid confinement structure 12 that faces the planar part 110B of the further surface 110. An arrangement of this type may be appropriate for example where it is impossible for the immersion liquid to reach the top part of the liquid confinement structure 12. In a variation on this embodiment the further surface 110 comprises only the frusto-conical part 110A and not the planar part 110B.

In an embodiment, a device manufacturing method is provided. The method comprises using a projection system PS to project a patterned radiation beam through the projection system PS onto a target portion C of a substrate W. The immersion fluid is confined in a space 10 between the projection system PS and the substrate W using a liquid confinement structure 12. The projection system PS comprises an exit surface 104 through which to project the patterned radiation beam. The projection system PS further comprises a further surface 110 facing the liquid confinement structure 12. The further surface 110 has a first static receding contact angle with respect to the immersion liquid. The exit surface 104 has a second static receding contact angle with respect to the immersion liquid. The first static receding contact angle is: greater than the second static receding contact angle; and less than 65 degrees.

In another embodiment, a device manufacturing method comprises using a projection system PS to project a patterned radiation beam through the projection system PS onto a target portion C of a substrate C. The immersion fluid is confined in a space 10 between the projection system PS and the substrate W using a liquid confinement structure 12. The projection system in this embodiment comprises an exit surface 104 through which to project the patterned radiation beam and a further surface 110 facing the liquid confinement structure 12. In this embodiment movement of the substrate W relative to the projection system PS causes fluctuations in the position of a line of contact 117 between a meniscus 22 of the immersion liquid and the further surface 110. The further surface 110 has a static receding contact angle with respect to the immersion liquid that is less than 90 degrees.

In an embodiment movement of the substrate W is such that a speed of movement of the line of contact 117 during the fluctuations is at all times lower than a theoretical maximum speed of movement of the line of contact, as determined by the static receding contact angle with respect to the immersion liquid of the further surface 110. In this way, significant formation of a liquid film on the further surface 110 during the fluctuations is avoided. Undesirable heat load due to evaporation of a liquid film on the further surface 110 is thereby also avoided.

In any of the embodiments discussed above the immersion liquid may be predominantly water. In this case all references to static receding contact angle may be understood to refer to static receding contact angle with respect to water. References to liquidphobic (or lyophobic) may be understood to refer to hydrophobic. References to liquidphilic (or lyophilic) may be understood to refer to hydrophilic.

In an embodiment there is provided a lithographic apparatus. The lithographic apparatus comprises: a projection system configured to project a patterned radiation beam through the projection system onto a target portion of a substrate; and a liquid confinement structure configured to confine an immersion liquid in a space between the projection system and the substrate. The projection system comprises: an exit surface through which to project the patterned radiation beam; and a further surface facing the liquid confinement structure, wherein: the further surface has a first static receding contact angle with respect to the immersion liquid; the exit surface has a second static receding contact angle with respect to the immersion liquid; and the first static receding contact angle is: greater than the second static receding contact angle; and less than 65 degrees.

The liquid confinement structure may be configured so that movement of the substrate relative to the projection system in use causes fluctuations in the position of a line of contact between a meniscus of the immersion liquid and the further surface.

In a further embodiment, there is provided: a lithographic apparatus, comprising a projection system configured to project a patterned radiation beam through the projection system onto a target portion of a substrate; and a liquid confinement structure configured to confine an immersion liquid in a space between the projection system and the substrate. The projection system comprises: an exit surface through which to project the patterned radiation beam; and a further surface facing the liquid confinement structure, wherein: the liquid confinement structure is configured so that movement of the substrate relative to the projection system in use causes fluctuations in the position of a line of contact between a meniscus of the immersion liquid and the further surface; and the further surface has a static receding contact angle with respect to the immersion liquid of less than 90 degrees.

The further surface may have a static receding contact angle with respect to the immersion liquid of less than 70 degrees. The further surface may have a static receding contact angle with respect to the immersion liquid of less than 65 degrees. The further surface may have a static receding contact angle with respect to the immersion liquid of greater than 30 degrees. The further surface may have a static receding contact angle with respect to the immersion liquid of greater than 50 degrees. The further surface may comprise a sloped surface angled obliquely to the exit surface. The further surface may comprise a planar surface parallel to the exit surface. The further surface may comprise a surface of a coating. The further surface may comprise an uncoated surface. The further surface may be provided on a passageway-former positioned between a last lens element of the projection system and the liquid confinement structure, the passageway-former defining a passageway between the passageway-former and the last lens element. The further surface may be provided by a liquid control member attached to, and conforming in shape with, a portion of the projection system. The liquid confinement structure may comprise a liquid control surface facing the projection system; and a portion of the liquid control surface has a static receding contact angle that is less than 90 degrees.

In a third embodiment there is provided a projection system for use with an immersion lithographic apparatus. The projection system is configured to project a patterned radiation beam through the projection system onto a target portion of a substrate. The projection system comprises: an exit surface through which to project the patterned radiation beam; and a further surface facing the liquid confinement structure. The further surface has a first static receding contact angle with respect to the immersion liquid. The exit surface has a second static receding contact angle with respect to the immersion liquid. The first static receding contact angle is: greater than the second static receding contact angle; and less than 65 degrees.

In a fourth embodiment of the invention there is provided a last lens element for a projection system of an immersion lithographic apparatus. The projection system is configured to project a patterned radiation beam through the projection system onto a target portion of a substrate. The projection system comprises: an exit surface through which to project the patterned radiation beam; and a further surface facing the liquid confinement structure. The further surface has a first static receding contact angle with respect to the immersion liquid. The exit surface has a second static receding contact angle with respect to the immersion liquid. The first static receding contact angle is: greater than the second static receding contact angle; and less than 65 degrees.

In a fifth embodiment of the invention there is provided a liquid control member, configured to be attached to, and conform in shape with, a portion of a projection system of an immersion lithographic apparatus. The projection system is configured to project a patterned radiation beam through the projection system onto a target portion of a substrate. The projection system comprises an exit surface through which to project the patterned radiation beam. The liquid control member comprises a further surface configured to face the liquid confinement structure when the liquid control member is attached to said portion of the projection system. The further surface has a first static receding contact angle with respect to the immersion liquid. The exit surface has a second static receding contact angle with respect to the immersion liquid. The first static receding contact angle is: greater than the second static receding contact angle; and less than 65 degrees.

The member may comprise a sloped surface angled obliquely to the exit surface when attached to said portion of the projection system. The member may comprise a frusto-conical portion when attached to said portion of the projection system. The member may comprise a planar portion parallel to the exit surface when attached to said portion of the projection system. The member may conform in shape with said portion of the projection system prior to attachment.

In a sixth embodiment of the invention there is provided the apparatus of the first or further embodiment, the system of the third embodiment, the element of the fourth embodiment or the member of the fifth embodiment, configured to operate with water as the immersion liquid, such that said static receding contact angle with respect to the immersion liquid is a static receding contact angle with respect to water.

In a seventh embodiment there is provided a device manufacturing method, comprising: using a projection system to project a patterned radiation beam through the projection system onto a target portion of a substrate; an confining an immersion fluid in a space between the projection system and the substrate using a liquid confinement structure, the projection system comprising: an exit surface through which to project the patterned radiation beam; and a further surface facing the liquid confinement structure, wherein: the further surface has a first static receding contact angle with respect to the immersion liquid; the exit surface has a second static receding contact angle with respect to the immersion liquid; and the first static receding contact angle is: greater than the second static receding contact angle; and less than 65 degrees.

In an eighth embodiment of the invention, there is provided a device manufacturing method, comprising: using a projection system to project a patterned radiation beam through the projection system onto a target portion of a substrate; and confining an immersion fluid in a space between the projection system and the substrate using a liquid confinement structure, the projection system comprising: an exit surface through which to project the patterned radiation beam; a further surface facing the liquid confinement structure, wherein: movement of the substrate relative to the projection system causes fluctuations in the position of a line of contact between a meniscus of the immersion liquid and the further surface; and the further surface has a static receding contact angle with respect to the immersion liquid that is less than 90 degrees.

Movement of the substrate may be such that a speed of movement of said line of contact during said fluctuations is at all times lower than a theoretical maximum speed of movement of said line of contact, as determined by the static receding contact angle with respect to the immersion liquid of the further surface.

In a ninth embodiment of the invention there is provided a lithographic apparatus, comprising: a projection system configured to project a patterned radiation beam through an exit surface of the projection system onto a target portion of a substrate; and a liquid confinement structure configured to confine an immersion liquid in a space between the projection system and the substrate, wherein the projection system comprises a further surface facing the liquid confinement structure and having a static receding contact angle with respect to the immersion liquid that is a) at least 10 degrees greater than a static receding contact angle with respect to the immersion liquid of the exit surface, and b) less than 65 degrees.

In a tenth embodiment of the invention there is provided a device manufacturing method, comprising: using a projection system to project a patterned radiation beam through an exit surface of the projection system onto a target portion of a substrate; and confining an immersion liquid in a space between the projection system and the substrate using a liquid confinement structure, wherein the projection system comprises a further surface facing the liquid confinement structure and having a static receding contact angle with respect to the immersion liquid that is a) at least 10 degrees greater than a static receding contact angle with respect to the immersion liquid of the exit surface, and b) less than 65 degrees.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The terms “radiation” and “beam” used herein encompass all types of electromagnetic radiation, including ultraviolet (UV) radiation (e.g. having a wavelength of or about 365, 248, 193, 157 or 126 nm) and extreme ultra-violet (EUV) radiation (e.g. having a wavelength in the range of 5-20 nm), as well as particle beams, such as ion beams or electron beams.

The term “lens”, where the context allows, may refer to any one or combination of various types of optical components, including refractive, reflective, magnetic, electromagnetic and electrostatic optical components.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A lithographic apparatus, comprising:
a projection system configured to project a patterned radiation beam through the projection system onto a target portion of a substrate; and
a liquid confinement structure configured to form a seal between the liquid confinement structure and the substrate so as to at least partly confine an immersion liquid in a space between the projection system and the substrate,
the projection system comprising:
an exit surface through which to project the patterned radiation beam; and
a further surface facing the liquid confinement structure, wherein:
the further surface has a first static receding contact angle with respect to the immersion liquid;
the exit surface has a second static receding contact angle with respect to the immersion liquid; and
the first static receding contact angle is:
greater than the second static receding contact angle; and
less than 65 degrees.

2. The apparatus of claim 1, wherein the liquid confinement structure is configured so that movement of the substrate relative to the projection system in use causes fluctuations in the position of a line of contact between a meniscus of the immersion liquid and the further surface.

3.-4. (canceled)

5. The apparatus of claim 1, wherein the further surface has a static receding contact angle with respect to the immersion liquid of greater than 30 degrees.

6. The apparatus of claim 1, wherein the further surface comprises a sloped surface angled obliquely to the exit surface.

7. The apparatus of claim 1, wherein the further surface comprises a planar surface parallel to the exit surface.

8. The apparatus of claim 1, further comprising a passageway-former positioned between a last lens element of the projection system and the liquid confinement structure, the passageway-former defining a passageway between the passageway-former and the last lens element and the further surface is provided on the passageway-former.

9. The apparatus of claim 1, wherein the further surface is provided by a liquid control member attached to, and conforming in shape with, a portion of the projection system.

10. The apparatus of claim 1, wherein:
the liquid confinement structure comprises a liquid control surface facing the projection system; and
a portion of the liquid control surface has a static receding contact angle that is less than 90 degrees.

11. (canceled)

12. A liquid control member, configured to be attached to, and conform in shape with, a portion of a projection system of an immersion lithographic apparatus, wherein:
the projection system is configured to project a patterned radiation beam through the projection system onto a target portion of a substrate;
the projection system comprises an exit surface through which to project the patterned radiation beam;
the liquid control member comprises a further surface configured to face a the liquid confinement structure of the lithographic apparatus when the liquid control member is attached to the portion of the projection system;
the further surface has a first static receding contact angle with respect to the immersion liquid;
the exit surface has a second static receding contact angle with respect to the immersion liquid; and
the first static receding contact angle is:
greater than the second static receding contact angle; and
less than 65 degrees.

13. The member of claim 12, wherein the member comprises a sloped surface angled obliquely to the exit surface when attached to the portion of the projection system.

14. The member of claim 12, wherein the member conforms in shape with the portion of the projection system prior to attachment.

15. A device manufacturing method, comprising:
using a projection system to project a patterned radiation beam through the projection system onto a target portion of a substrate; and
using a liquid confinement structure to form a seal between the liquid confinement structure and the substrate so as to at least partly confine an immersion fluid in a space between the projection system and the substrate, the projection system comprising:
an exit surface through which to project the patterned radiation beam; and
a further surface facing the liquid confinement structure, wherein:
the further surface has a first static receding contact angle with respect to the immersion liquid;
the exit surface has a second static receding contact angle with respect to the immersion liquid; and
the first static receding contact angle is:
greater than the second static receding contact angle; and
less than 65 degrees.

16. The method of claim 15, further comprising causing fluctuations in the position of a line of contact between a meniscus of the immersion liquid and the further surface due to movement of the substrate relative to the projection system.

17. The method of claim 15, wherein the further surface has a static receding contact angle with respect to the immersion liquid of greater than 30 degrees.

18. The method of claim 15, wherein the further surface comprises a sloped surface angled obliquely to the exit surface.

19. The method of claim 15, wherein the further surface comprises a planar surface parallel to the exit surface.

20. The method of claim 15, wherein the further surface is provided by a liquid control member attached to, and conforming in shape with, a portion of the projection system.

21. The method of claim 15, wherein the liquid confinement structure comprises a liquid control surface facing the projection system, a portion of the liquid control surface having a static receding contact angle that is less than 90 degrees.

22. The member of claim 12, wherein the further surface has a static receding contact angle with respect to the immersion liquid of greater than 30 degrees.

23. The member of claim 12, wherein the further surface comprises a planar surface parallel to the exit surface.
